(19) United States
(12) Patent Application Publication
(10) Pub. No.: US 2022/0298456 A1
(43) Pub. Date: Sep. 22, 2022

(54) CLEANING LIQUID, METHOD OF CLEANING, AND METHOD OF MANUFACTURING SEMICONDUCTOR WAFER

(71) Applicant: Mitsubishi Chemical Corporation, Tokyo (JP)

(72) Inventors: Longjie AN, Tokyo (JP); Tomohiro KUSANO, Tokyo (JP); Yukako ONO, Tokyo (JP); Kan TAKESHITA, Tokyo (JP); Kenichi KIYONO, Tokyo (JP)

(73) Assignee: Mitsubishi Chemical Corporation, Tokyo (JP)

(21) Appl. No.: 17/829,682

(22) Filed: Jun. 1, 2022

Related U.S. Application Data
(63) Continuation of application No. PCT/JP2020/043512, filed on Nov. 20, 2020.

(30) Foreign Application Priority Data
Dec. 3, 2019 (JP) 2019-218699

(51) Int. Cl. C11D 7/36; C11D 7/08; C11D 7/26; C11D 7/32; C11D 11/00; C09G 1/02; H01L 21/306

(52) U.S. Cl. CPC C11D 7/36; C11D 7/08; C11D 7/265; C11D 7/268; C11D 7/3209; C11D 11/0047; C09G 1/02; H01L 21/30625

(57) ABSTRACT

The present invention relates to a cleaning liquid on a silicon oxide film and/or a silicon nitride film, and the cleaning liquid contains (i) at least one compound selected from the group consisting of a compound represented by the formula (1), a compound represented by formula (2), a compound represented by formula (3), and a compound represented by the formula (4); and (ii) a reducing agent;

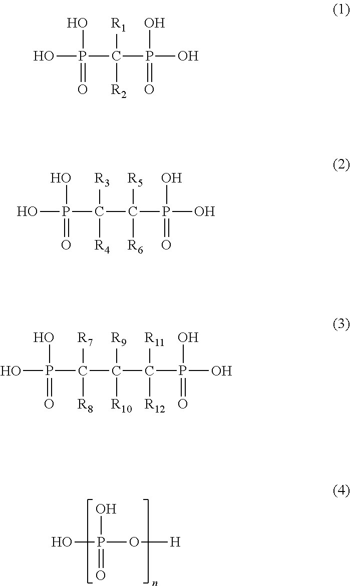

in the above formulas, R₁ to R₁₂ and n are the same as the definitions described in the description.

### TECHNICAL FIELD

The present invention relates to a cleaning liquid, a method of cleaning, and a method of manufacturing a semiconductor wafer.

### BACKGROUND ART

A semiconductor wafer is manufactured by deposition of layers of a metal film working as a wiring and an interlayer insulating film on a silicon substrate, subsequently conducting a surface planarization by means of a chemical mechanical polishing (hereinafter referred to as “CMP”) step with an abrasive composed of an aqueous slurry containing fine abrasive particles, and then stacking new layers on the planarized surface. In microfabrication of a semiconductor wafer, each layer is required to have planarity with high precision, and importance of the planarization treatment by means of CMP is very high.

In a semiconductor device manufacturing process, in order to electrically separate an element such as a transistor, an element isolation structure by shallow trench isolation (STI) suitable for miniaturization is used instead of conventional Local Oxidation of Silicon (LOCOS). Additionally, an interlayer dielectric (ILD) is used between the wiring layers. STI and ILD are produced by forming a silicon oxide film using tetraethyl orthosilicate (TEOS) or the like as a raw material and planarizing the film in a CMP step.

Many fine abrasive particles and organic residues derived from organic compounds contained in the slurry are present on the surface of the semiconductor wafer after the CMP step. Therefore, in order to remove them, the semiconductor wafer after the CMP step is subjected to a cleaning step.

In recent years, in the CMP step of a silicon oxide film or a silicon nitride film, cerium-based abrasive fine particles such as cerium oxide are used to increase the polishing rate. However, since the cerium-based abrasive fine particles form bonds with the surface of the silicon oxide film or the silicon nitride film during the CMP step, it is difficult to remove the abrasive fine particles in the cleaning step.

Therefore, conventionally, cleaning is performed with strong chemicals such as diluted hydrofluoric acid or combination of sulfuric acid and hydrogen peroxide. Various cleaning liquids have been proposed as alternative cleaning liquids to diluted hydrofluoric acid, sulfuric acid and hydrogen peroxide from the viewpoint of safety and waste liquid treatment. For example, Patent Literature 1 discloses a cleaning liquid containing a reducing agent. In addition, Patent Literature 2 discloses a cleaning liquid containing diphosphonic acid and hydrogen peroxide.

### CITATION LIST

### Patent Literature

Patent Literature 1: JP-A-H11-251280
Patent Literature 2: JP-A-2004-022986

### SUMMARY OF INVENTION

### Technical Problem

However, since the cleaning liquid disclosed in Patent Literature 1 does not contain a chelating agent, there is a problem that the cerium compound is difficult to dissolve in the cleaning liquid and the cleaning liquid disclosed in Patent Literature 1 is poor in removability for the cerium compound. In addition, the cleaning liquid disclosed in Patent Literature 1 has a problem that it is necessary to heat the cleaning liquid in order to dissolve the cerium compound in the cleaning liquid.

Since the cleaning liquid disclosed in Patent Literature 2 does not contain a reducing agent, it cannot break a bond between the cerium compound and the silicon oxide, and has a problem that the cleaning liquid disclosed in Patent Literature 2 is poor in removability for the cerium compound. In addition, since the cleaning liquid disclosed in Patent Literature 2 contains hydrogen peroxide which is easily decomposed in the cleaning liquid, there is a problem that the long-term quality stability of the cleaning liquid is poor.

The present invention has been made in view of such a problem, and an object of the present invention is to provide a cleaning liquid having excellent removability for a cerium compound.

### Solution to Problem

Previously, cleaning liquids containing various components have been considered. As a result of intensive studies, the inventors of the present invention have found out a cleaning liquid containing (i) at least one compound and (ii) a reducing agent, which will be described later, and found that this cleaning liquid has excellent removability for the cerium compound.

Namely, the gist of the present invention is as follows.

[1] A cleaning liquid comprising

(i) at least one compound selected from the group consisting of a compound represented by the formula (1), a compound represented by formula (2), a compound represented by formula (3), and a compound represented by the formula (4); and

(ii) a reducing agent;

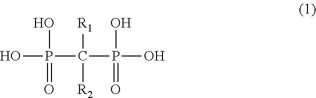

wherein, in formula (1), R₁ and R₂ each independently represents a hydrogen atom, an alkyl group having 1 to 4 carbon atoms which may be optionally substituted with a substituent, a carboxyl group, a carbonyl group, a chemical structure having an ester bond, an amino group, a hydroxyl group or a phosphonic acid group;

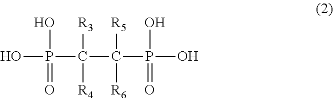

wherein, in formula (2), R₃, R₄, R₅ and R₆ each independently represents a hydrogen atom, an alkyl group having 1 to 4 carbon atoms which may be optionally substituted with a substituent, a carboxyl group, a carbonyl group, a chemical structure having an ester bond, an amino group, a hydroxyl group or a phosphonic acid group;

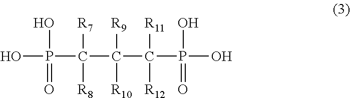

wherein, in formula (3), R₇, R₈, R₉, R₁₀, R₁₁ and R₁₂ each independently represents a hydrogen atom, an alkyl group having 1 to 4 carbon atoms which may be optionally substituted with a substituent, a carboxyl group, a carbonyl group, a chemical structure having an ester bond, an amino group, a hydroxyl group or a phosphonic acid group; and

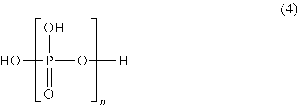

wherein, in formula (4), n represents an arbitrary integer.

[2] The cleaning liquid according to [1], wherein the (i) at least one compound comprises at least one selected from the group consisting of etidronic acid, alendronic acid, metaphosphoric acid, pyrophosphoric acid and polyphosphoric acid.

[3] The cleaning liquid according to [1], wherein the (i) at least one compound comprises etidronic acid.

[4] The cleaning liquid according to [1], wherein the (ii) reducing agent comprises at least one selected from the group consisting of ascorbic acid, gallic acid, phosphinic acid, glucose, oxalic acid, pyrogallol, pyrocatechol and glyoxal.

[5] The cleaning liquid according to [1], wherein the (ii) reducing agent comprises at least one selected from the group consisting of phosphinic acid, glucose and pyrogallol.

[6] The cleaning liquid according to [1], further comprising a water-soluble organic polymer.

[7] The cleaning solution according to [6], wherein the water-soluble organic polymer comprises at least one of a polycarboxylic acid or a salt thereof.

[8] The cleaning liquid according to [1], further comprising a pH regulator.

[9] The cleaning liquid according to [8], wherein the pH regulator comprises at least one of ammonia or a quaternary ammonium salt.

[10] The cleaning liquid according to [1], wherein pH of the cleaning liquid is within a range from 1 to 7.

[11] The cleaning liquid according to [1], wherein a weight ratio of the (i) at least one compound to the (ii) reducing agent is in a range from 1 to 100.

[12] The cleaning liquid according to [1], wherein pH of the cleaning liquid is within a range from 1.5 to 6.

[13] The cleaning liquid according to [1], wherein pH of the cleaning liquid is within a range from 2 to 5.

[14] The cleaning liquid according to [1], wherein a weight ratio of the (i) at least one compound to the (ii) reducing agent is in a range from 1 to 10.

[15] A method of cleaning comprising: removing a cerium compound on a silicon oxide film and/or a silicon nitride film with the cleaning liquid according to [1].

[16] A method of manufacturing a semiconductor wafer, comprising: removing a cerium compound on a silicon oxide film and/or a silicon nitride film with the cleaning liquid according to [1].

[17] The method of manufacturing a semiconductor wafer according to [16], further comprising: performing a chemical mechanical polishing with an abrasive containing a cerium compound.

[18] The cleaning liquid according to [6], wherein a weight average molecular weight of the water-soluble organic polymer is in a range from 100 to 20,000.

[19] The cleaning liquid according to [1], wherein a weight ratio of the (i) at least one compound to the water-soluble organic polymer is in a range from 0.05 to 20.

[20] The cleaning liquid according to [1], wherein a weight ratio of the (i) at least one compound to the water-soluble organic polymer is in a range from 0.2 to 5.

### Advantageous Effects of Invention

The cleaning liquid of the present invention has excellent removability for a cerium compound.

In addition, the method of cleaning of the present invention has excellent removability for a cerium compound.

Further, since the method of manufacturing a semiconductor wafer of the present invention includes a cleaning step which has excellent removability for a cerium compound, it is possible to prevent an operation failure of a semiconductor device.

### DESCRIPTION OF EMBODIMENTS

Hereinafter, embodiments of the present invention are specifically described, but it should not be construed that the present invention is limited to the following embodiments, and the present invention can be carried out by making various changes within the scope of a gist thereof. In the present description, the expression “to” is used as an expression including numerical values or physical property values before and after the expression.

### [Cleaning Liquid]

A cleaning liquid of the present invention is used for removing a cerium compound, is suitably used for removing a cerium compound on a silicon oxide film and/or a silicon nitride film, and particularly preferably used for removing a cerium compound on a silicon oxide film.

Note that “a cerium compound on a silicon oxide film and/or a silicon nitride film” means at least one cerium compound selected from the group consisting of a cerium compound on a silicon oxide film and a cerium compound on a silicon nitride film.

Hereinafter, each component will be described in detail.

((i) at least one compound)

The cleaning liquid of the present invention contains,

(i) at least one compound selected from the group consisting of a compound represented by the formula (1), a compound represented by formula (2), a compound represented by formula (3), and a compound represented by the formula (4)

(ii) a reducing agent

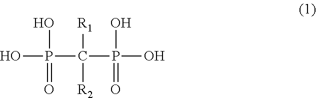

In formula (1). R₁ and R₂ each independently represents a hydrogen atom, an alkyl group having 1 to 4 carbon atoms which may be optionally substituted with a substituent, a carboxyl group, a carbonyl group, a chemical structure having an ester bond, an amino group, a hydroxyl group or a phosphonic acid group.

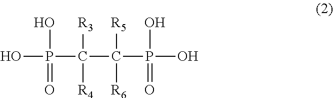

In formula (2), R₃, R₄, R₅ and R₆ each independently represents a hydrogen atom, an alkyl group having 1 to 4 carbon atoms which may be optionally substituted with a substituent, a carboxyl group, a carbonyl group, a chemical structure having an ester bond, an amino group, a hydroxyl group or a phosphonic acid group.

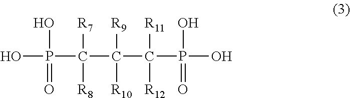

In formula (3), R₇, R₈, R₉, R₁₀, R₁₁ and R₁₂ each independently represents a hydrogen atom, an alkyl group having 1 to 4 carbon atoms which may be optionally substituted with a substituent, a carboxyl group, a carbonyl group, a chemical structure having an ester bond, an amino group, a hydroxyl group or a phosphonic acid group.

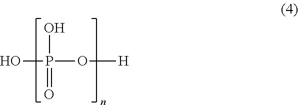

In formula (4), n represents an arbitrary integer.

Containing the (i) at least one compound, the cleaning liquid of the present invention acts selectively on cerium ions, can break a bond between a cerium compound and a silicon oxide without damaging the silicon oxide film or the silicon nitride film, and has excellent removability for a cerium compound and low damage to the silicon oxide film or the silicon nitride film.

Among the (i) at least one compound, the compound represented by formula (1) and the compound represented by formula (4) are preferred since a 6-membered ring complex is formed with the cerium compound and the removability for the cerium compound is improved, and the compound represented by formula (1) is more preferred since it is not hydrolyzed and the stability is improved.

Examples of the alkyl group having 1 to 4 carbon atoms in the general formulas (1) to (3) include a methyl group, an ethyl group, an n-propyl group, an isopropyl group, an n-butyl group, an isobutyl group, a sec-butyl group, and a tert-butyl group.

Examples of the substituent that the alkyl group may have include a hydroxyl group, a carboxyl group, a carbonyl group, and an amino group.

Examples of the chemical structure having an ester bond in the formulas (1) to (3) include a sulfate ester and a phosphate ester.

R₁ and R₂ in formula (1) are preferably each independently a hydrogen atom, an alkyl group having 1 to 4 carbon atoms which may be may be optionally substituted with a substituent, or a hydroxyl group since it is easy to synthesize the compound represented by formula (1), more preferably each independently a hydrogen atom, an alkyl group having 1 to 2 carbon atoms which may be may be optionally substituted with a substituent, or a hydroxyl group since the compound represented by formula (1) is easily soluble in water, and still more preferably a combination of a methyl group and a hydroxyl group.

R₃, R₄, R₅, and R₆ in formula (2) are preferably each independently a hydrogen atom, an alkyl group having 1 to 4 carbon atoms which may be optionally substituted with a substituent, or a hydroxyl group since it is easy to synthesize the compound represented by formula (2), more preferably each independently a hydrogen atom, an alkyl group having 1 to 2 carbon atoms which may be optionally substituted with a substituent, or a hydroxyl group since the compound represented by formula (2) is easily soluble in water, and still more preferably a combination of a methyl group and a hydroxyl group.

R₇, R₈, R₉, R₁₀, R₁₁, and R₁₂ in formula (3) are preferably each independently a hydrogen atom, an alkyl group having 1 to 4 carbon atoms which may be optionally substituted with a substituent, or a hydroxyl group since it is easy to synthesize the compound represented by formula (3), more preferably each independently a hydrogen atom, an alkyl group having 1 to 2 carbon atoms which may be optionally substituted with a substituent, or a hydroxyl group since the compound represented by formula (3) is easily soluble in water, and still more preferably a combination of a methyl group and a hydroxyl group.

In formula (4), n is preferably 2 to 10,000, and more preferably 10 to 2,000. When n is 2 or more, the chelating action improves the removability for the cerium compound and improves the dispersion stability. When n is 10,000 or less, hydrolysis of the compound represented by formula (4) is prevented.

Specific examples of the (i) at least one compound include etidronic acid, alendronic acid, metaphosphoric acid, pyrophosphoric acid, and polyphosphoric acid. These (i) at least one compound may be used alone or in combination of two or more thereof.

Among these (i) at least one compound, etidronic acid, pyrophosphoric acid, and polyphosphoric acid are preferred since it is acidic and easily soluble, forms a 6-membered ring complex with the cerium compound, and improves the removability for the cerium compound, etidronic acid and polyphosphoric acid are more preferred since the dispersion stability is improved, and etidronic acid is still more preferred since it is not hydrolyzed and the stability is improved.

((ii) Reducing Agent)

The cleaning liquid of the present invention contains (ii) a reducing agent

Containing the (ii) reducing agent, the cleaning liquid of the present invention acts selectively on cerium ions, can break a bond between a cerium compound and a silicon oxide without damaging the silicon oxide film or the silicon nitride film, and has improved removability for a cerium compound and low damage to the silicon oxide film or the silicon nitride film.

Specifically, when a tetravalent cerium ion and a silicon oxide are bonded to each other, and the tetravalent cerium ion is reduced to trivalent by the (ii) reducing agent, the bond strength between the cerium compound and the silicon oxide is weakened, thus improving the removability for the cerium compound.

Examples of the (ii) reducing agent include ascorbic acid (L-ascorbic acid, D-ascorbic acid, and isoascorbic acid), gallic acid (gallic acid anhydrous and monohydrate of gallic acid), methyl gallate, phosphinic acid, glucose, oxalic acid, hydrazine, hydroxylamine, thiourea dioxide, sodium hydrosulfite, pyrogallol, pyrocatechol, and glyoxal. These (ii) reducing agent may be used alone or in combination of two or more thereof.

Among these (ii) reducing agent, since the reducing power is excellent, ascorbic acid, gallic acid, phosphinic acid, glucose, oxalic acid, pyrogallol, pyrocatechol, and glyoxal are preferred, L-ascorbic acid, gallic acid, phosphinic acid, glucose, and pyrogallol are more preferred, L-ascorbic acid, phosphinic acid, glucose, and pyrogallol are more preferred, and phosphinic acid, glucose, and pyrogallol are particularly preferred.

(Water-Soluble Organic Polymer)

It is preferable that the cleaning liquid of the present invention further contains a water-soluble organic polymer since it disperses the cerium compound and improves the removability for the cerium compound.

Examples of the water-soluble organic polymer include a polycarboxylic acid and a salt of the polycarboxylic acid. Examples of the polycarboxylic acid include polyacrylic acid and polymethacrylic acid. Examples of the salt of the polycarboxylic acid include a salt of polyacrylic acid and a salt of polymethacrylic acid. These water-soluble organic polymers may be used alone or in combination of two or more thereof.

Among these water-soluble organic polymers, a polycarboxylic acid or a salt of the polycarboxylic acid is preferred, and a salt of polyacrylic acid or polyacrylic acid is more preferred since it is easily dissolved in an acidic aqueous solution.

The polycarboxylic acid may be a homopolymer of a carboxylic acid-containing monomer or a copolymer of a carboxylic acid-containing monomer and another monomer.

The weight average molecular weight of the water-soluble organic polymer is preferably 100 to 20,000, and more preferably 200 to 10,000. When the weight average molecular weight of the water-soluble organic polymer is 100 or more, the cerium compound is dispersed by the water-soluble organic polymer and the removability for the cerium compound is improved. In addition, when the weight average molecular weight of the water-soluble organic polymer is 20,000 or less, it is easily dissolved in water.

(pH Regulator)

It is preferable that the cleaning liquid of the present invention further contains a pH regulator since the pH of the cleaning liquid can be adjusted.

Examples of the pH regulator include an acid and an alkali. Among these pH regulators, an alkali is preferred since the degree of acid dissociation of the water-soluble organic polymer can be adjusted and the cerium compound can be dispersed, ammonia or a quaternary ammonium salt is more preferable since it does not contain a metal component, and ammonia is still more preferred.

(Water)

It is preferable that the cleaning liquid of the present invention further contains water since the removability for fine particles is improved.

Examples of the water include ion exchange water, distilled water, and ultrapure water. Among these, ultrapure water is preferred from the viewpoint of further enhancing the removability for the cerium compound.

(Other Components)

The cleaning liquid of the present invention may contain components other than the (i) at least one compound, the (ii) reducing agent, the water-soluble organic polymer, the pH regulator, and water as long as the effects of the present invention are not impaired.

Examples of the other component include a chelating agent other than the (i) at least one compound, a surfactant, and an etching inhibitor.

(Physical Properties of Cleaning Liquid)

The pH of the cleaning liquid is preferably within a range from 1 to 7, more preferably within a range from 1.5 to 6, and still more preferably within a range from 2 to 5. When the pH of the cleaning liquid is 1 or more, damage to members such as brushes used in the cleaning step of a semiconductor wafer and the like can be prevented. In addition, when the pH of the cleaning liquid is 7 or less, the removability for the cerium compound is remarkably improved by the synergistic effect of the chelating effect of the (i) at least one compound and the reducing effect of the (ii) reducing agent.

(Mass Ratio of Components)

The mass ratio of the (i) at least one compound to the (ii) reducing agent (mass of (i) at least one compound/mass of (ii) reducing agent) is preferably in a range from 0.1 to 100, more preferably in a range from 1 to 100, and still more preferably in a range from 1 to 10. When the mass ratio of the (i) at least one compound to the (ii) reducing agent is 0.1 or more, the chelating effect improves the removability for the cerium compound and the low damage to the silicon oxide film or the silicon nitride film. In addition, when the mass ratio of the (i) at least one compound to the (ii) reducing agent is 100 or less, the reducing effect improves the removability for the cerium compound and the low damage to the silicon oxide film or the silicon nitride film.

When the cleaning liquid of the present invention contains the water-soluble organic polymer, the mass ratio of the water-soluble organic polymer to the (i) at least one compound (mass of water-soluble organic polymer/mass of (i) at least one compound) is preferably in a range from 0.05 to 20, more preferably in a range from 0.1 to 10, and still more preferably in a range from 0.2 to 5. When the mass ratio of the water-soluble organic polymer to the (i) at least one compound is 0.05 or more, the dispersion effect improves the removability for the cerium compound. In addition, when the mass ratio of the water-soluble organic polymer to the (i) at least one compound is 20 or less, the chelating effect improves the removability for the cerium compound and the low damage to the silicon oxide film or the silicon nitride film.

When the cleaning liquid of the present invention contains the water-soluble organic polymer, the mass ratio of the water-soluble organic polymer to the (ii) reducing agent (mass of water-soluble organic polymer/mass of (ii) reducing agent) is preferably in a range from 0.1 to 100, more preferably in a range from 1 to 100, and still more preferably in a range from 1 to 10. When the mass ratio of the water-soluble organic polymer to the (ii) reducing agent is 0.1 or more, the dispersion effect improves the removability for the cerium compound. In addition, when the mass ratio of the water-soluble organic polymer to the (ii) reducing agent is 100 or less, the reducing effect improves the removability for the cerium compound and the low damage to the silicon oxide film or the silicon nitride film.

(Content of Each Component in Cleaning Liquid)

The content of the (i) at least one compound is preferably in a range from 0.001% by mass to 30% by mass, more preferably in a range from 0.005% by mass to 20% by mass, and still more preferably in a range from 0.01% by mass to 1% by mass in 100% by mass of the cleaning liquid. When the content of the (i) at least one compound is 0.001% by mass or more, the chelating effect improves the removability for the cerium compound and the low damage to the silicon oxide film or the silicon nitride film. In addition, when the content of the (i) at least one compound is 30% by mass or less, the (i) at least one compound can be sufficiently dissolved in the water, and the production cost of the cleaning liquid can be reduced when the cleaning liquid contains the water.

The content of the (ii) reducing agent is preferably in a range from 0.0001% by mass to 30% by mass, more preferably in a range from 0.0005% by mass to 20% by mass, and still more preferably in a range from 0.001% by mass to 1% by mass in 100% by mass of the cleaning liquid. When the content of the (ii) reducing agent is 0.0001% by mass or more, the reducing effect improves the removability for the cerium compound and the low damage to the silicon oxide film or the silicon nitride film. In addition, when the content of the (ii) reducing agent is 30% by mass or less, the (ii) reducing agent can be sufficiently dissolved in the water, and the production cost of the cleaning liquid can be reduced when the cleaning liquid contains the water.

When the cleaning liquid of the present invention contains the water-soluble organic polymer, the content of the water-soluble organic polymer is preferably in a range from 0.001% by mass to 30% by mass, more preferably in a range from 0.005% by mass to 20% by mass, and still more preferably in a range from 0.01% by mass to 1% by mass in 100% by mass of the cleaning liquid. When the content of the water-soluble organic polymer is 0.001% by mass or more, the dispersion effect improves the removability for the cerium compound. In addition, when the content of the water-soluble organic polymer is 30% by mass or less, the water-soluble organic polymer can be sufficiently dissolved in the water, and the production cost of the cleaning liquid can be reduced when the cleaning liquid contains the water.

When the cleaning liquid of the present invention contains the pH regulator, the content of the pH regulator is preferably in a range from 0.001% by mass to 30% by mass, more preferably in a range from 0.005% by mass to 20% by mass, and still more preferably in a range from 0.01% by mass to 1% by mass in 100% by mass of the cleaning liquid. When the content of the pH regulator is 0.001% by mass or more, the pH of the cleaning liquid can be easily adjusted. In addition, when the content of the pH regulator is 30% by mass or less, the pH of the cleaning liquid can be adjusted without impairing the effect of the present invention.

When the cleaning liquid of the present invention contains other components, the content of the other components is preferably in a range from 20% by mass or less, more preferably in a range from 0.0001% by mass to 10% by mass, and still more preferably in a range from 0.001% by mass to 1% by mass in 100% by mass of the cleaning liquid. When the content of the other components is 20% by mass or less, the effects of other components can be imparted without impairing the effect of the present invention.

When the cleaning liquid of the present invention contains the water, the content of the water is preferably the balance of the components (the (i) at least one compound, the (ii) reducing agent, the water-soluble organic polymer, the pH regulator, and other components) other than the water.

(Method of Producing Cleaning Liquid)

The method of producing the cleaning liquid of the present invention is not particularly limited, and the cleaning liquid can be produced by mixing the (i) at least one compound, the (ii) reducing agent, and, if necessary, the water-soluble organic polymer, the pH regulator, the water, and the other components.

The order of mixing is not particularly limited, and all the components may be mixed at one time, or some components may be mixed in advance and then the remaining components may be mixed.

In the method of producing the cleaning liquid of the present invention, each component may be blended to have a content suitable for cleaning, or a cleaning liquid containing each component other than the water may be prepared at a high content, and then the cleaning liquid may be prepared by diluting with the water before cleaning since transportation and storage costs can be reduced.

The dilution ratio can be appropriately set depending on an object to be cleaned, and is preferably from 30 times to 150 times, and more preferably from 40 times to 120 times.

(Object to be Cleaned)

Examples of the object to be cleaned of the cleaning liquid of the present invention include semiconductor wafers, glass, metals, ceramics, resins, magnetic materials, and superconductors. Among these objects to be cleaned, since the effect of the present invention is remarkably improved, those having a surface on which a silicon oxide film or a silicon nitride film is exposed are preferred, a semiconductor wafer having a surface on which a silicon oxide film or a silicon nitride film is exposed is more preferred, and a semiconductor wafer having a surface on which a silicon oxide film is exposed is still more preferred.

In addition to a silicon oxide and a silicon nitride, a metal may coexist on the surface of the semiconductor wafer having a surface on which the silicon oxide film or the silicon nitride film is exposed.

(Type of Cleaning Step)

Since the cleaning liquid of the present invention has excellent removability for the cerium compound, the cleaning liquid can be suitably used for cleaning after chemical mechanical polishing.

The chemical mechanical polishing (CMP) step refers to a step of mechanically processing and planarizing the surface of a semiconductor wafer. In general, in the CMP step, using a dedicated device, a back side of the semiconductor wafer is attached to a jig called platen, and the surface of the semiconductor wafer is pressed against a polishing pad, and a polishing agent containing abrasive particles is dropped onto the polishing pad to polish the surface of the semiconductor wafer.

(CMP)

The CMP is performed by rubbing the object to be polished against the polishing pad by using an abrasive.

The polishing agent is not particularly limited as long as polishing agent is insoluble in water and can polish the object to be polished. Since the effect of the cleaning liquid of the present invention can be sufficiently exhibited, fine abrasive particles are preferred, and the fine abrasive particles of the cerium compound are more preferred.

The fine abrasive particles may contain colloidal silica (SiO₂), fumed silica (SiO₂), or alumina (Al₂O₃) in addition to the fine abrasive particles of the cerium compound.

Examples of the cerium compound include cerium oxide and cerium hydroxide. These cerium compounds may be used alone or in combination of two or more thereof. Among these cerium compounds, cerium oxide and cerium hydroxide are preferred, and cerium oxide is more preferred due to excellent polishing rate and low scratch property.

The abrasive may contain additives such as an oxidizing agent and a dispersant in addition to the abrasive fine particles. In particular, in CMP in a semiconductor wafer having a surface on which a metal is exposed, a metal is likely to be corroded, and thus an anticorrosive agent is often contained.

When the cleaning liquid of the present invention is applied to a semiconductor wafer having a surface on which a silicon oxide film or a silicon nitride film is exposed after polishing with an abrasive containing fine abrasive particles of such a cerium compound, contamination of the semiconductor wafer derived from the cerium compound can be removed extremely effectively.

(Cleaning Conditions)

The method of cleaning the object to be cleaned is preferably a method of bringing the cleaning liquid of the present invention into direct contact with the object to be cleaned.

Examples of the method of bringing the cleaning liquid of the present invention into direct contact with the object to be cleaned include: a dipping method in which a cleaning tank is filled with the cleaning liquid of the present invention to immerse the object to be cleaned; a spin method of rotating the object to be cleaned at a high speed while allowing the cleaning liquid of the present invention to flow from a nozzle onto the object to be cleaned; and a spray method of spraying and cleaning the cleaning liquid of the present invention onto the object to be cleaned. Among these methods, the spin method and the spray method are preferred since more efficient decontamination can be performed in a short time.

Examples of an apparatus for performing such cleaning include a batch cleaning apparatus for simultaneously cleaning a plurality of objects to be cleaned, which are accommodated in a cassette, and a single-wafer cleaning apparatus for mounting a single object to be cleaned on a holder and performing cleaning. Among these apparatuses, a single wafer cleaning apparatus is preferred since the cleaning time can be shortened the amount of the cleaning liquid of the present invention to be used can be reduced.

The method of cleaning an object to be cleaned is preferably performed by physical force since the removability for fine particles attached to the object to be cleaned is further improved and the cleaning time can be shortened. Scrub cleaning with a cleaning brush and ultrasonic cleaning with a frequency of 0.5 megahertz, or more is more preferred, and scrub cleaning with a resin brush is still more preferred since the scrub cleaning with the resin brush is more suitable for cleaning after the CMP step.

Although the material of the resin brush is not particularly limited, polyvinyl alcohol or polyvinyl formal is preferred due to easy production of the resin brush itself.

The cleaning temperature may be room temperature, and may be heated to from 30° C. to 70° C. as long as the performance of the semiconductor wafer is not impaired.

### [Method of Cleaning]

The method of cleaning of the present invention is a method including removing a cerium compound on a silicon oxide film and/or a silicon nitride film with the cleaning liquid of the present invention, as described above.

### [Method of Manufacturing Semiconductor Wafer]

The method of manufacturing a semiconductor wafer of the present invention is a method including removing a cerium compound on a silicon oxide film and/or a silicon nitride film with the cleaning liquid of the present invention, and preferably includes performing chemical mechanical polishing with an abrasive containing a cerium compound.

### EXAMPLES

Hereinafter, the present invention is demonstrated further more concretely by ways of Examples, but the present invention is not limited to following Examples, unless the gist of the present invention is exceeded.

(Raw Materials)

(i-1): etidronic acid (manufactured by FUJIFILM Wako Pure Chemical Corporation)

(i-2): polyphosphoric acid (manufactured by FUJIFILM Wako Pure Chemical Corporation)

(i′-1): citric acid (manufactured by Showa Kako Corporation)

(ii-1): ascorbic acid (manufactured by FUJIFILM Wako Pure Chemical Corporation)

(ii-2): monohydrate of gallic acid (manufactured by FUJIFILM Wako Pure Chemical Corporation)

(ii-3): phosphinic acid (manufactured by FUJIFILM Wako Pure Chemical Corporation)

(ii-4): glucose (manufactured by Tokyo Chemical Industry Co., Ltd.)

Water-soluble organic polymer 1: polyacrylic acid (manufactured by Sigma-Aldrich, weight average molecular weight: about 2,000)

Water-soluble organic polymer 2: polyacrylic acid (manufactured by FUJIFILM Wako Pure Chemical Corporation, weight average molecular weight: about 5,000)

(pH Measurement)

The pH of the cleaning liquids obtained in Examples and Comparative Examples was measured by a pH meter (model name “D-74”, manufactured by Horiba, Ltd.) with stirring using a magnetic stirrer.

(Measurement of Residual Amount of Cerium Oxide)

A silicon substrate on which a silicon oxide film was formed by a plasma chemical vapor deposition (CVD) method with tetraethoxysilane (TEOS) was cut into a size of 30 mm×30 mm. Next, the silicon substrate was subjected to chemical mechanical polishing (CMP) for 30 seconds with an abrasive containing cerium oxide (aqueous dispersion of cerium oxide fine particles having a particle diameter of 200 nm or less) and a polishing pad (trade name “IC1000”, manufactured by Nitta Haas Co., Ltd.).

Next, the silicon substrate was put in the cleaning liquids obtained in Examples and Comparative Examples and cleaned for 5 minutes. Next, the silicon substrate was rinsed with water and dried, and the amount of cerium oxide remaining on the surface of the silicon substrate (μg/cm²) was measured with an X-ray fluorescence analyzer (model name “ZSX100e”, manufactured by Rigaku Corporation).

### Example 1

In 100% by mass of the cleaning liquid, the components were mixed such that the (i-1): etidronic acid was 0.10% by mass, the (ii-1): ascorbic acid was 0.09% by mass, and the balance was the water, and a cleaning liquid was obtained.

The evaluation results of the obtained cleaning liquid are shown in Table 1.

### Examples 2 to 10 and Comparative Examples 1 to 8

A cleaning liquid was obtained in the same manner as in Example 1, except that the type and content of the raw materials were as shown in Table 1.

The evaluation results of the obtained cleaning liquid are shown in Table 1.

TABLE 1

| | | | | | | Water-Soluble Organic | | | Residual |
|---|---|---|---|---|---|---|---|---|---|
| | | (i) at least one | | | | Polymer | | | amount of |
| | | compound | | (ii) reducing agent | | | Content | | cerium |
| | | | Content (% | | Content (% | | (% by | | oxide |
| | | Type | by mass) | Type | by mass) | Type | mass) | pH | (μg/cm²) |
| Example | 1 | (i-1) | 0.10 | (ii-1) | 0.09 | — | — | 2.3 | 0.19 |
| | 2 | (i-2) | 0.10 | (ii-2) | 0.04 | — | — | 2.0 | 0.10 |
| | 3 | (i-2) | 0.10 | (ii-1) | 0.04 | Water-Soluble | 0.10 | 2.0 | 0.17 |
| | | | | | | Organic Polymer 1 | | | |
| | 4 | (i-2) | 0.10 | (ii-1) | 0.04 | Water-Soluble | 0.10 | 2.0 | 0.19 |
| | | | | | | Organic Polymer 2 | | | |
| | 5 | (i-1) | 0.10 | (ii-1) | 0.08 | — | — | 2.3 | 0.11 |
| | 6 | (i-1) | 0.10 | (ii-3) | 0.04 | — | — | 2.0 | 0.13 |
| | 7 | (i-2) | 0.10 | (ii-2) | 0.02 | — | — | 2.0 | 0.12 |
| | 8 | (i-1) | 0.10 | (ii-4) | 0.04 | — | — | 2.3 | 0.25 |
| | 9 | (i-1) | 0.10 | (ii-4) | 0.08 | — | — | 2.3 | 0.15 |
| | 10 | (i-1) | 0.10 | (ii-4) | 0.20 | — | — | 2.3 | 0.30 |
| Comparative | 1 | (i-1) | 0.10 | — | — | — | — | 2.3 | 0.45 |
| Example | 2 | — | — | (ii-1) | 0.09 | — | — | 3.3 | 0.54 |
| | 3 | — | — | (ii-2) | 0.04 | — | — | 3.6 | 0.83 |
| | 4 | — | — | (ii-3) | 0.04 | — | — | 2.3 | 0.88 |
| | 5 | — | — | (ii-4) | 0.02 | — | — | 4.7 | 0.99 |
| | 6 | — | — | (ii-1) | 0.04 | — | — | 6.3 | 1.06 |
| | 7 | (i′-1) | 0.10 | (ii-1) | 0.09 | — | — | 2.7 | 0.40 |
| | 8 | (i′-1) | 0.10 | (ii-2) | 0.04 | — | — | 2.7 | 0.51 |

As can be seen from Table 1, the cleaning liquids obtained in Examples 1 to 10 containing the (i) at least one compound and the (ii) reducing agent at the same time were excellent in removability for cerium oxide.

On the other hand, the cleaning liquids obtained in Comparative Examples 1 to 8 containing neither the (i) at least one compound nor the (ii) reducing agent were poor in removability for cerium oxide.

Although the present invention has been described in detail using specific embodiments, it will be apparent to those skilled in the art that various modifications and variations are possible without departing from the spirit and scope of the present invention. The present application is based on a Japanese Patent Application (Japanese Patent Application No. 2019-218699) filed on Dec. 3, 2019, contents of which are incorporated herein by reference.

### INDUSTRIAL APPLICABILITY

Since the cleaning liquid of the present invention has excellent removability for a cerium compound on a silicon oxide film and/or a silicon nitride film, the cleaning liquid can be suitably used for cleaning after chemical mechanical polishing.

1. A cleaning liquid comprising:
(i) at least one compound selected from the group consisting of a compound represented by the formula (1), a compound represented by formula (2), a compound represented by formula (3), and a compound represented by the formula (4); and
(ii) a reducing agent; 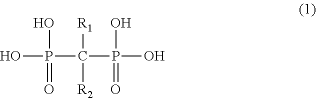
wherein, in formula (1), R₁ and R₂ each independently represents a hydrogen atom, an alkyl group having 1 to 4 carbon atoms which may be optionally substituted with a substituent, a carboxyl group, a carbonyl group, a chemical structure having an ester bond, an amino group, a hydroxyl group or a phosphonic acid group; 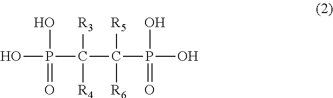
wherein, in formula (2), R₃, R₄, R₅ and R₆ each independently represents a hydrogen atom, an alkyl group having 1 to 4 carbon atoms which may be optionally substituted with a substituent, a carboxyl group, a carbonyl group, a chemical structure having an ester bond, an amino group, a hydroxyl group or a phosphonic acid group; 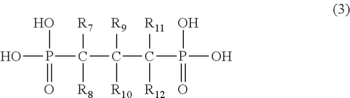
wherein, in formula (3), R₇, R₈, R₉, R₁₀, R₁₁ and R₁₂ each independently represents a hydrogen atom, an alkyl group having 1 to 4 carbon atoms which may be optionally substituted with a substituent, a carboxyl group, a carbonyl group, a chemical structure having an ester bond, an amino group, a hydroxyl group or a phosphonic acid group; and 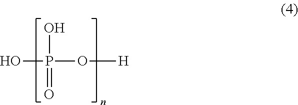
wherein, in formula (4), n represents an arbitrary integer.

2. The cleaning liquid according to claim 1, wherein the (i) at least one compound comprises at least one selected from the group consisting of etidronic acid, alendronic acid, metaphosphoric acid, pyrophosphoric acid and polyphosphoric acid.

3. The cleaning liquid according to claim 1, wherein the (i) at least one compound comprises etidronic acid.

4. The cleaning liquid according to claim 1, wherein the (ii) reducing agent comprises at least one selected from the group consisting of ascorbic acid, gallic acid, phosphinic acid, glucose, oxalic acid, pyrogallol, pyrocatechol and glyoxal.

5. The cleaning liquid according to claim 1, wherein the (ii) reducing agent comprises at least one selected from the group consisting of phosphinic acid, glucose and pyrogallol.

6. The cleaning liquid according to claim 1, further comprising a water-soluble organic polymer.

7. The cleaning solution according to claim 6, wherein the water-soluble organic polymer comprises at least one of a polycarboxylic acid or a salt thereof.

8. The cleaning liquid according to claim 1, further comprising a pH regulator.

9. The cleaning liquid according to claim 8, wherein the pH regulator comprises at least one of ammonia or a quaternary ammonium salt.

10. The cleaning liquid according claim 1, wherein pH of the cleaning liquid is within a range from 1 to 7.

11. The cleaning liquid according to claim 1, wherein a weight ratio of the (i) at least one compound to the (ii) reducing agent is in a range from 1 to 100.

12. The cleaning liquid according claim 1, wherein pH of the cleaning liquid is within a range from 1.5 to 6.

13. The cleaning liquid according claim 1, wherein pH of the cleaning liquid is within a range from 2 to 5.

14. The cleaning liquid according to claim 1, wherein a weight ratio of the (i) at least one compound to the (ii) reducing agent is in a range from 1 to 10.

15. A method of cleaning comprising:
removing a cerium compound on a silicon oxide film and/or a silicon nitride film with the cleaning liquid according to claim 1.

16. A method of manufacturing a semiconductor wafer, comprising:
removing a cerium compound on a silicon oxide film and/or a silicon nitride film with the cleaning liquid according to claim 1.

17. The method of manufacturing a semiconductor wafer according to claim 16, further comprising: performing a chemical mechanical polishing with an abrasive containing a cerium compound.

18. The cleaning liquid according to claim 6, wherein a weight average molecular weight of the water-soluble organic polymer is in a range from 100 to 20,000.

19. The cleaning liquid according to claim 1, wherein a weight ratio of the (i) at least one compound to the water-soluble organic polymer is in a range from 0.05 to 20.

20. The cleaning liquid according to claim 1, wherein a weight ratio of the (i) at least one compound to the water-soluble organic polymer is in a range from 0.2 to 5.
